(19) United States
(12) Patent Application Publication
(10) Pub. No.: US 2011/0312184 A1
(43) Pub. Date: Dec. 22, 2011

(54) METHOD FOR FORMING PATTERN OF SEMICONDUCTOR DEVICE

(75) Inventors: Byoung Hoon LEE, Seoul (KR); Jong Sik Bang, Pyeongtaek (KR)

(73) Assignee: Hynix Semiconductor Inc., Icheon-si (KR)

(21) Appl. No.: 12/980,275

(22) Filed: Dec. 28, 2010

(30) Foreign Application Priority Data
Jun. 17, 2010 (KR) 10-2010-0057505

(51) Int. Cl. H01L 21/311

(52) U.S. Cl. 438/696; 257/E21.249

(57) ABSTRACT

A method for forming a pattern of a semiconductor device is disclosed. The method for forming the semiconductor device pattern can simplify a fabrication process using Spacer Patterning Technology (SPT), and at the same time can form a microscopic contact hole. The method for forming the semiconductor device pattern includes forming a hard mask layer and a photoresist film pattern over an underlying layer to be etched; forming one or more first spacers over sidewalls of the photoresist film pattern; removing the photoresist film pattern; forming a sacrificial film pattern by burying a sacrificial film in a region between the first spacers; after removing the first spacer, and forming one or more second spacers over sidewalls of the sacrificial film pattern; after removing the sacrificial film pattern, etching the hard mask layer using the second spacer as an etch mask, and forming a hard mask pattern; and forming a contact hole pattern by etching the underlying layer using the hard mask layer pattern as a mask.

### CROSS-REFERENCE TO RELATED APPLICATION

The priority of Korean patent application No. 10-2010-0057505 filed on 17 Jun. 2010, the disclosure of which is hereby incorporated in its entirety by reference, is claimed.

### BACKGROUND OF THE INVENTION

Embodiments of the present invention relate to a method for forming a pattern of a semiconductor device, and more particularly to a method for forming a pattern of a semiconductor device using a method for forming a contact hole using Spacer Patterning Technology (SPT).

Although an entire chip area is increased in proportion to an increase in memory capacity as a semiconductor device is becoming super miniaturized and highly integrated, the area of a cell area where patterns of a semiconductor device are actually formed is decreased.

Accordingly, since a greater number of patterns should be formed in a limited cell area in order to achieve a desired memory capacity, the size of such pattern, for example, the critical dimension (CD) or spacing between patterns, is being gradually decreased. Such microscopic patterns are formed by a photolithography process.

In the photolithography process, a photoresist layer is deposited over a substrate, an exposure process is performed using a laser beam having a wavelength of 365 nm, 248 nm (KrF), 193 nm (ArF) or 153 nm and an exposure mask on which a circuit pattern is drawn, and a development process is finally performed to form a pattern.

Increases in the degree of integration of semiconductor devices necessitate a reduction in design rules, causing the pitch size of patterns of the semiconductor device to be increasingly reduced. However, photographic devices capable of forming such patterns generally have a limited resolution, so that it is difficult to form patterns having a microscopic (or fine) pitch. In particular, in order to form patterns having a microscopic pitch, a pattern mask should be used several times, and fabrication of the pattern mask is also complicated, so that there are limitations in forming a microscopic pattern. For example, since the pattern mask is used multiple times, it is difficult to solve the problem of misaligning a mask, a semiconductor device is unexpectedly contaminated in each fabrication process.

In conclusion, a method for simplifying a fabrication process and at the same time forming a microscopic pattern such as a contact hole is needed.

### BRIEF SUMMARY OF THE INVENTION

Various embodiments of the present invention are directed to providing a method for forming a pattern of a semiconductor device that substantially obviates one or more problems due to limitations and disadvantages of the conventional art.

An object of the present invention is to provide a method for forming a pattern of a semiconductor device using a method for forming a contact hole using a Spacer Patterning Technology (SPT).

In accordance with an aspect of the present invention, In accordance with an aspect of the present invention, A method for forming a pattern of a semiconductor device comprising: forming a photoresist film pattern over an underlying layer and a hard mask layer; forming a plurality of first spacers over sidewalls of the photoresist film pattern; removing the photoresist film; forming a sacrificial film pattern between the first spacers; removing the first spacers after forming the sacrificial film pattern; forming a plurality of second spacers over sidewalls of the sacrificial film pattern; removing the sacrificial film; and etching the hard mask layer using the second spacers as an etch mask.

The photoresist film pattern may be a pillar pattern. Forming of the photoresist film pattern may be performed through a single patterning using a single exposure mask or a double exposure process using a line/space mask.

Forming of the photoresist film pattern may include forming a hard mask layer and a photoresist film over the underlying layer to be etched; performing pillar patterning using an exposure mask on the photoresist film, forming a first pillar pattern having critical dimension (CD) grater than a target CD; and trimming the first pillar pattern to change the CD to the target CD.

The method may further include forming a Bottom Anti Reflection Coating (BARC) film between the photoresist film pattern and the underlying layer including the hard mask layer. The first spacers are formed to be in contact with one another in a first direction. The first spacers are formed to be spaced apart from one in a second direction. The first direction is diagonal to the second direction.

The region between the first spacers, the region between the first spacers may include a region the sidewalls of first spacers. The first spacer and the second spacer are formed using any one of a nitride film, an oxide film, or a combination thereof.

The forming of the first spacer and the second spacer may be performed through an Atomic Layer Deposition (ALD) process. The ALD process may be performed at a temperature of about 0° C.˜ about 200° C.

The hard mask layer may be configured in a stacked structure of an amorphous carbon (a-carbon) layer and a silicon oxide nitride (SiON) film. The forming of the sacrificial film may include forming a polysilicon layer over the hard mask layer including the first spacer; and planarizing the hard mask layer until the first spacer is exposed. The polysilicon layer may be formed at a temperature of about 300˜ about 500° C. The etching of the underlying layer may include forming a hard mask layer pattern by etching the hard mask layer; and etching the underlying layer using the hard mask layer pattern as a mask, and forming a contact hole pattern.

The second spacers are formed to be in contact with one another in a first direction. The second spacers may be formed to be spaced apart from one another in a second direction.

The first direction is diagonal to the second. A contact hole pattern region may be defined by a space between the second spacers.

A method for forming a pattern of a semiconductor device comprising: providing a semiconductor substrate having a target etch layer thereover; forming pillar patterns over the target etch layer, the pillar patterns being arranged in a diamond format; forming a first spacer over a sidewall of each of the pillar patterns so as to generate a first trench at the center of the diamond format; removing the pillar patterns to form a second trench at each vertex of the diamond format; providing sacrificial material into the first and the second trenches to form sacrificial film patterns, the sacrificial film patterns being arranged in a square format; removing the first spacers after forming the sacrificial film patterns; forming a second spacer over a sidewall of the sacrificial film pattern; removing the sacrificial film pattern after forming the second spacer; and etching the target etch layer layer using the second spacer as an etch mask.

A diagonal length of the square defined by the sacrificial film patterns is shorter than a diagonal length of the diamond defined by the pillar patterns. The length of one side of the square formed of the sacrificial film patterns is half a diagonal length of the diamond formed of the pillar patterns, wherein the width of the second spacer is half a width of the sacrificial film pattern. The pillar pattern is formed to have a first dimension, the second spacer is formed to have a second dimension smaller than the first dimension, and the sacrificial film pattern is formed to have a size smaller than the first dimension.

### BRIEF DESCRIPTION OF THE DRAWINGS

FIGS. 1 to 9 are cross-sectional views and plan views illustrating a method for forming a pattern of a semiconductor device according to embodiments of the present invention.

### DESCRIPTION OF EMBODIMENTS

Reference will now be made in detail to the embodiments of the present invention, examples of which are illustrated in the accompanying drawings. Wherever possible, the same reference numbers will be used throughout the drawings to refer to the same or like parts. A semiconductor device and a method for manufacturing the same according to the present invention will hereinafter be described with reference to the accompanying drawings.

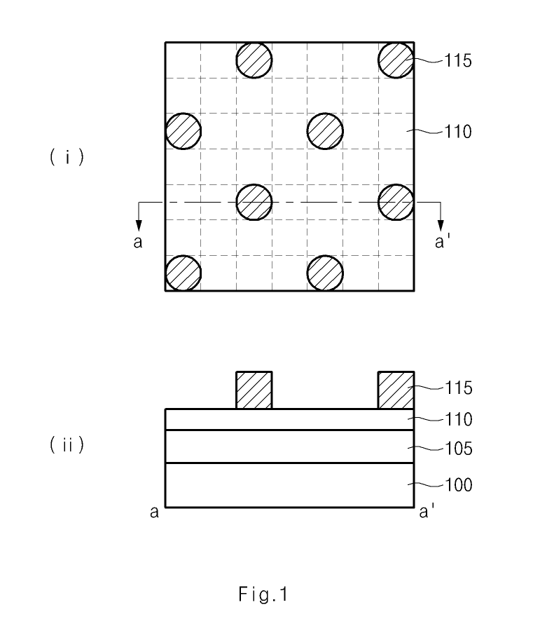

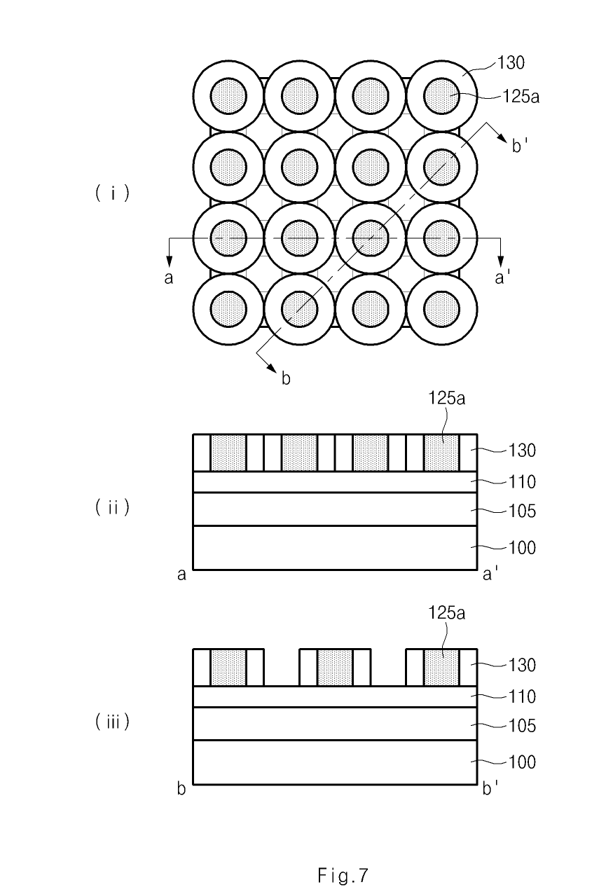

FIGS. 1 to 9 are cross-sectional views and plan views illustrating a method for forming a pattern of a semiconductor device according to embodiments of the present invention. FIGS. 1(i) to 9(i) are plan views illustrating a semiconductor device according to the present invention. FIGS. 1(ii) to 9(ii) are cross-sectional views illustrating a semiconductor device taken along the line a-a′ of FIGS. 1(i) to 9(i). FIG. 7(iii) is a cross-sectional view illustrating a semiconductor taken along the line b-b′ of FIG. 7(i).

Referring to FIG. 1, an underlying layer 105 is formed over a semiconductor substrate 100, a hard mask layer 110 is formed over the underlying layer 105, and a photoresist film (not shown) is formed over the hard mask layer 110. Subsequently, pillar patterning is performed through a photographic process using an exposure mask to form photoresist film pattern 115. The photoresist film pattern 115 may be formed using a single exposure mask or by a double exposure process using a Line/Space mask.

In addition, if a Critical Dimension (CD) of the photoresist film pattern 115 is too small, patterns may collapse during the pattern forming. In order to prevent the collapse of patterns, a CD of the photoresist film pattern 115 is formed to be larger than a target CD, and the pattern may be subsequently reduced through a trimming process

The hard mask layer 110 may be a stacked structure of an amorphous carbon (a-carbon) and a silicon oxide nitride (SiON) film. A Bottom Anti Reflection Coating (BARC) layer (not shown) may be formed at the bottom of the photoresist film (not shown). If the BARC layer is formed at the bottom of the photoresist film pattern 115, a process for etching the BARC layer may be carried out using the photoresist film pattern 115 before a spacer layer is formed.

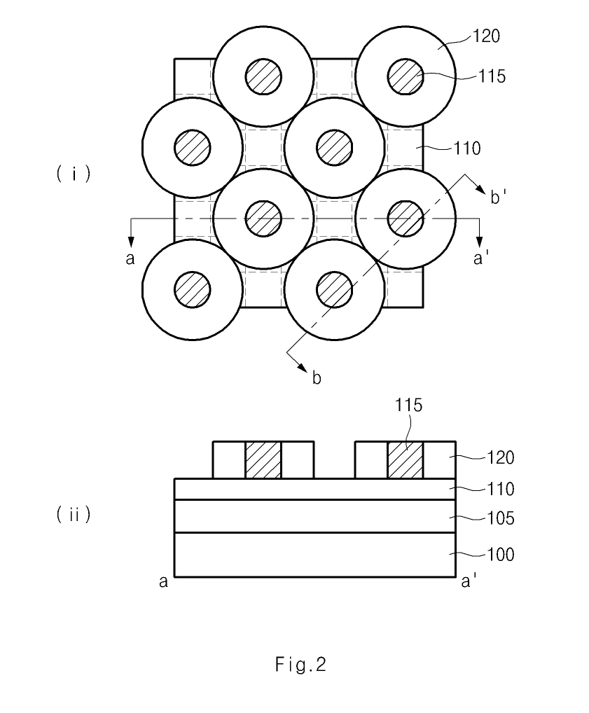

Referring to FIG. 2, an Atomic Layer Deposition (ALD) process is performed on the entire surface including the photoresist film pattern 115, so that a first spacer layer is formed through the ALD process. In this case, the ALD process may be performed at a temperature of about 200° C. or less, and the first spacer layer may be formed of a nitride film, an oxide film, or a combination thereof. An etch-back process is performed to etch back the first spacer layer until the photoresist film pattern 115 is exposed, so that first spacers 120 are formed over sidewalls of the photoresist film pattern 115, but not over the upper surface.

In this case, as shown in FIG. 2(i), the first spacers 120 are not in contact with each other between pillar patterns neighboring with each other in the a-a′ direction, so that the hard mask layer 110 is exposed. The first spacers 120 are in contact with each other between photoresist film patterns 115 neighboring with each other in the b-b′ direction, so that the hard mask layer 110 is not exposed. In other words, since a distance between the first spacers 120 neighboring with each other in the a-a′ direction is longer than a distance between the first spacers 120 neighboring with each other in the b-b′ direction, the first spacers 120 of the photoresist film patterns 115 neighboring with each other in the b-b′ direction are brought into contact with each other, and the first spacers 120 of the photoresist film patterns 115 neighboring with each other in the a-a′ direction are not in contact with each other.

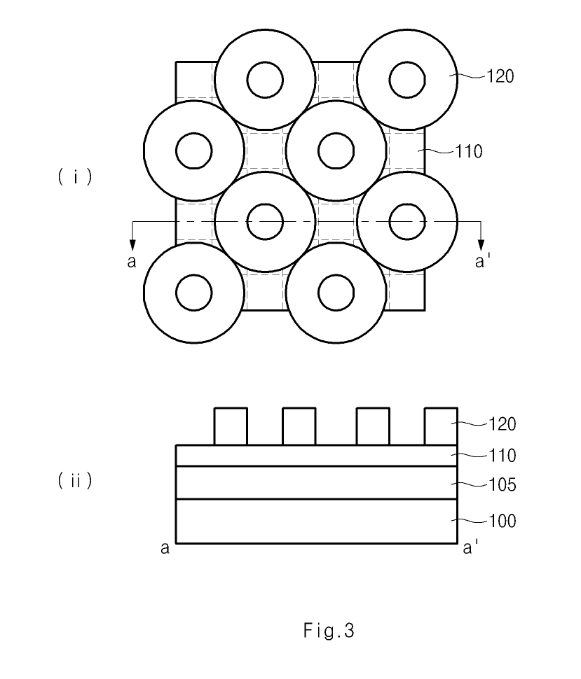

Referring to FIG. 3, the photoresist film pattern 115 is removed. In embodiments where the photoresist film pattern 115 is removed, the removal of the photoresist film pattern 115 generates first contact holes along both a-a′ and b-b′ directions at the location where the photoresist film patterns 115 existed and a second contact hole between first spacers 120 in the a-a′ direction.

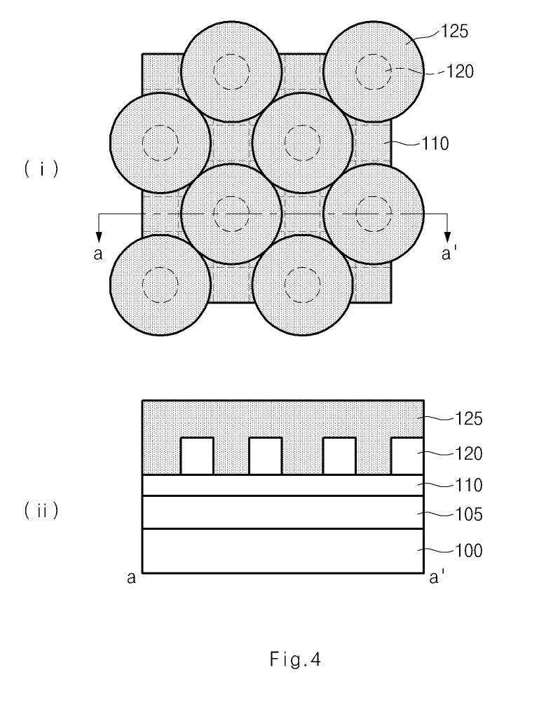

Referring to FIG. 4, a sacrificial film 125 is formed over the hard mask layer 110 including the first spacer 120. Preferably, the sacrificial film 125 may be formed of a material including polysilicon at a temperature of about 300° C.˜ about 500° C.

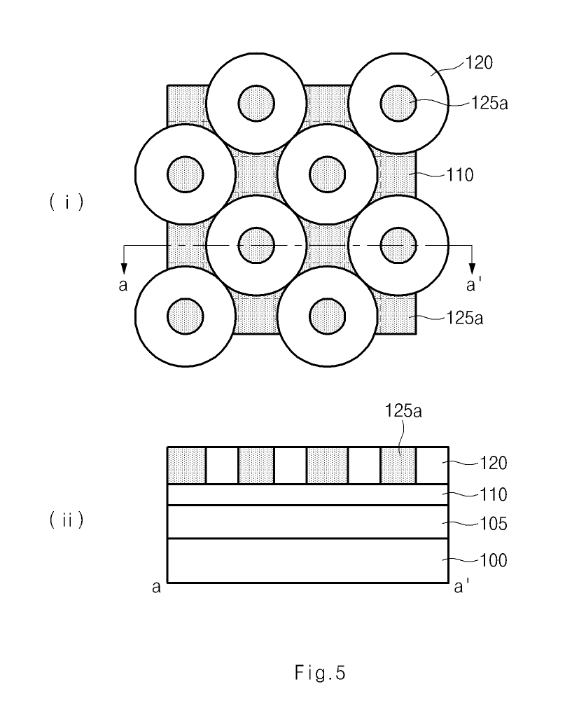

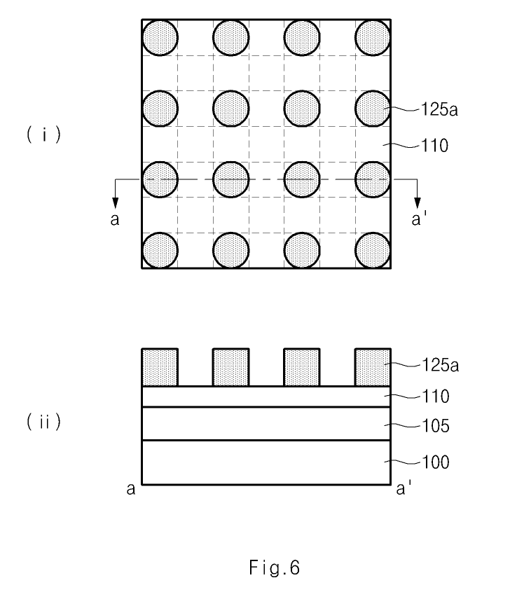

Referring to FIG. 5, the sacrificial film 125 is planarized until the first spacers 120 are exposed, leaving portions of the sacrificial film 125a between the first spacers 120, e.g., the first and the second contact holes. Afterwards, referring to FIG. 6, the first spacers 120 are removed leaving the sacrificial film 125a filling in the first and the second contact holes. In this embodiment, it is apparent that the total number of potential contact hole regions shown in FIG. 6(i) which are defined by the combination of the first and the second contact hole is increased compared with the total number of potential contact hole regions shown in FIG. 1(i) which are defined by the first contact hole only.

Referring to FIG. 7, a second spacer layer surrounding the sacrificial film pattern 125a is formed by an ALD process. In this case, the ALD process is performed at a low temperature of about 200° C. or less, and the second spacer layer may be formed of a nitride film, an oxide film, or a combination thereof.

Afterwards, an etch-back process is performed until the sacrificial film pattern 125a is exposed, so that second spacers 130 are formed over sidewalls of the sacrificial film pattern 125a. In this case, as shown in FIG. 7(i), the second spacers 130 are in contact with each other in the a-a′ direction, so that the hard mask layer 110 is not exposed. The second spacers 130 are not in contact with each other in the b-b′ direction so that the hard mask layer 110 is exposed. The b-b′ direction is angled against the a-a′ direction by more than zero and less than 90 degrees. In an embodiment, the b-b′ direction defines 45 degrees with respect to the a-a′ direction.

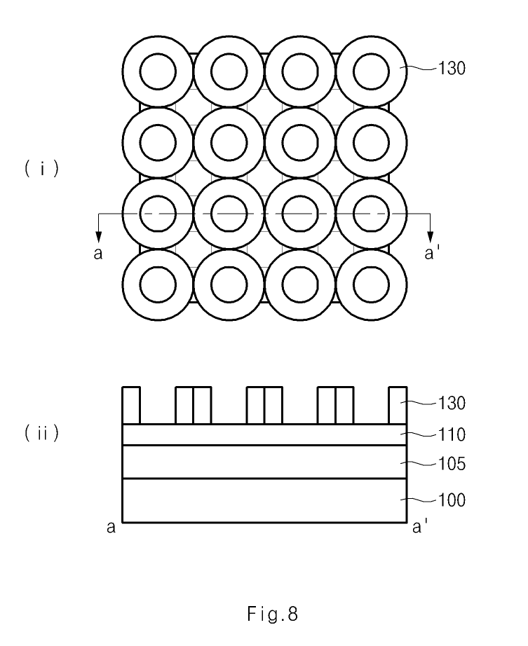

Referring to FIG. 8, the sacrificial film pattern 125a is removed so that the second spacers 130 remain. If the sacrificial film pattern 125a is removed, portions of the hard mask 110 that are between second spacers 130, as well as portions of the hard mask 110 that were under the film pattern 125a are exposed.

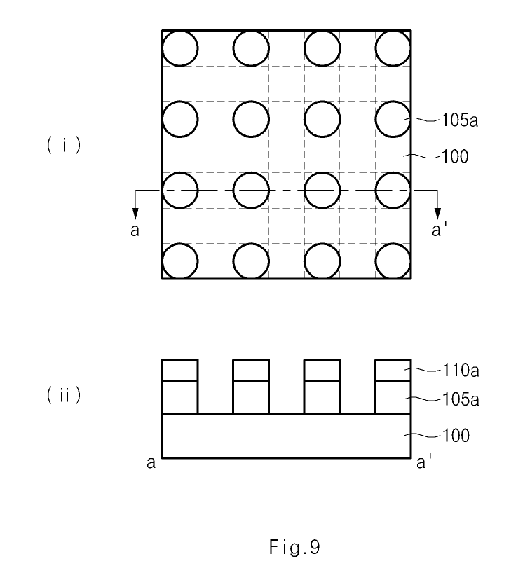

Referring to FIG. 9, a hard mask layer 110 is etched using the second spacer 130 as an etch mask, so that the hard mask pattern 110a is formed. Thereafter, the underlying layer 105 is etched using the hard mask pattern 110a as an etch mask, and the hard mask pattern 110a is removed, so that a microscopic (fine) pattern 105a for defining the contact hole region is formed. In various embodiments, individual contact hole regions are formed to have the same size through adjusting the size of the initial film pattern and the spacer thickness.

As apparent from the above description, a method for forming a pattern of a semiconductor device according to the embodiment of the present invention can form a microscopic hole pattern or pillar pattern through only one photographic process, resulting in a reduction in production costs of the semiconductor device.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or a nonvolatile memory device. Other additions, subtractions, or modifications are obvious in view of the present disclosure and are intended to fall within the scope of the appended claims.

What is claimed is:

1. A method for forming a pattern of a semiconductor device comprising:
forming a photoresist film pattern over an underlying layer and a hard mask layer;
forming a plurality of first spacers over sidewalls of the photoresist film pattern;
removing the photoresist film pattern;
forming a sacrificial film pattern between the first spacers;
removing the first spacers after forming the sacrificial film pattern;
forming a plurality of second spacers over sidewalls of the sacrificial film pattern;
removing the sacrificial film; and
etching the hard mask layer using the second spacers as an etch mask.

2. The method according to claim 1, wherein the photoresist film pattern is a pillar pattern.

3. The method according to claim 1, wherein forming the photoresist film pattern includes:
performing a single patterning by using a single exposure mask or a double exposure process by using a line/space mask.

4. The method according to claim 1, wherein forming the photoresist film pattern includes:
forming the hard mask layer and a photoresist film over the underlying layer;
performing pillar patterning using an exposure mask on the photoresist film;
forming a first pillar pattern having a critical dimension (CD) greater than a target CD; and
trimming the first pillar pattern to change the CD to the target CD.

5. The method according to claim 1, wherein the first spacers are formed to be in contact with one another in a first direction.

6. The method according to claim 5, wherein the first spacers are formed to be spaced apart from one another in a second direction.

7. The method according to claim 6, wherein the first direction is diagonal to the second direction.

8. The method according to claim 1, wherein the region between the first spacers includes a region between the sidewalls of first spacers.

9. The method according to claim 1, wherein the first spacer and the second spacer comprise any of a nitride film, an oxide film, or a combination thereof.

10. The method according to claim 1, wherein the first spacer and the second spacer are formed using an Atomic Layer Deposition (ALD) process.

11. The method according to claim 1, wherein the forming the sacrificial film pattern includes:
forming a polysilicon layer over the hard mask layer including the first spacer; and
planarizing the hard mask layer to expose the first spacer.

12. The method according to claim 1, wherein etching the underlying layer includes:
forming a hard mask layer pattern by etching the hard mask layer; and
etching the underlying layer by using the hard mask layer pattern as a mask, and forming a contact hole pattern.

13. The method according to claim 1, wherein the second spacers are formed to be in contact with one another in a first direction.

14. The method according to claim 13, wherein the second spacers are formed to be spaced apart from one another in a second direction.

15. The method according to claim 14, wherein the first direction is diagonal to the second direction.

16. The method according to claim 12, wherein a contact hole pattern region is defined by a space between the second spacers.

17. A method for forming a pattern of a semiconductor device comprising:
providing a semiconductor substrate having a target etch layer thereover;
forming pillar patterns over the target etch layer, the pillar patterns being arranged in a diamond format;
forming a first spacer over a sidewall of each of the pillar patterns so as to generate a first trench at the center of the diamond format;
removing the pillar patterns to form a second trench at each vertex of the diamond format;
providing sacrificial material into the first and the second trenches to form sacrificial film patterns, the sacrificial film patterns being arranged in a square format;
removing the first spacers after forming the sacrificial film patterns;
forming a second spacer over a sidewall of the sacrificial film pattern;
removing the sacrificial film pattern after forming the second spacer; and
etching the target etch layer layer using the second spacer as an etch mask.

18. The method of claim 17, wherein a diagonal length of the square defined by the sacrificial film patterns is shorter than a diagonal length of the diamond defined by the pillar patterns.

19. The method of claim 17, wherein the length of one side of the square formed of the sacrificial film patterns is half a diagonal length of the diamond formed of the pillar patterns,
wherein the width of the second spacer is half a width of the sacrificial film pattern.

20. The method of claim 17, wherein the pillar pattern is formed to have a first dimension,
wherein the second spacer is formed to have a second dimension smaller than the first dimension, and
wherein the sacrificial film pattern is formed to have a size smaller than the first dimension.
